(19) United States
(12) Patent Application Publication
(10) Pub. No.: US 2026/0330099 A1
(43) Pub. Date: Oct. 22, 2026

(54) SYSTEMS AND METHODS FOR EXECUTING PARAMETER CHANGES IN SCIENTIFIC MODELS USING MACHINE LEARNING

(71) Applicants: Constructor Technology AG, Schaffhausen (CH); Constructor Education and Research Genossenschaft, Schaffhausen (CH)

(72) Inventors: Alexander Tormasov, Bremen (DE); Laurent Dedenis, Geneve (CH); Stanislav Protasov, Singapore (SG); Serg Bell, Singapore (SG); Nikolay Dobrovolskiy, Alanya (TR)

(21) Appl. No.: 19/180,301

(22) Filed: Apr. 16, 2025

(51) Int. Cl. G06F 30/27

(52) U.S. Cl. CPC G06F 30/27

(57) ABSTRACT

A system receives a user query to change a parameter in a pre-existing scientific model. The system executes a first machine learning model configured to detect the parameter in a code of the pre-existing scientific model, wherein the first machine learning model outputs at least one fragment of the code that is associated with the parameter. The system executes a second machine learning model configured to: receive both the user query and the at least one fragment of the code as inputs; generate a new part of the code for the at least one fragment, wherein the new part of the code changes the parameter in accordance with the user query; and modify the code of the pre-existing scientific model to include the new part of the code. The system outputs a modified version of the pre-existing scientific model with the modified code.

### FIELD OF TECHNOLOGY

The present disclosure relates to the field of machine learning, and, more specifically, to systems and methods for executing parameter changes in scientific models using machine learning.

### BACKGROUND

Scientists and researchers often deal with complex models described in research papers, ranging from computational simulations in physics to machine learning algorithms in computer science. These models typically have various parameters that can significantly influence their behavior and outcomes. However, there is no convenient way for scientists and researchers to experiment with said models and potentially verify/improve them – especially if the code of a model is inaccessible or beyond the expertise of a scientist/researcher.

### SUMMARY

Aspects of the disclosure enable a user to change parameters of a pre-existing scientific model. A first machine learning model of the present disclosure detects code associated with the parameter to be changed. A second machine learning model of the present disclosure generates new code for adjusting the parameter based on user preference.

In an exemplary aspect, the techniques described herein relate to a method for executing a parameter change in a scientific model, the method including: receiving a user query to change a parameter in a pre-existing scientific model; executing a first machine learning model configured to detect the parameter in a code of the pre-existing scientific model, wherein the first machine learning model outputs at least one fragment of the code that is associated with the parameter; executing a second machine learning model configured to: receive both the user query and the at least one fragment of the code as inputs; and generate a new part of the code for the at least one fragment, wherein the new part of the code changes the parameter in accordance with the user query; modifying the code of the pre-existing scientific model to include the new part of the code; and outputting a modified version of the pre-existing scientific model with the modified code.

In some aspects, the techniques described herein relate to a method, wherein the pre-existing scientific model does not include an explicit value corresponding to the parameter, wherein the code of the pre-existing scientific model detected by the first machine learning model includes a plurality of sub-parameters that equal the parameter when combined.

In some aspects, the techniques described herein relate to a method, wherein the user query is received via a user interface, further including: identifying a plurality of components in the pre-existing scientific model; generating, for display on a computing device, the user interface including a plurality of visual objects corresponding to the plurality of components, wherein the plurality of visual objects are visually connected in a chain representing a workflow, and wherein at least one visual object includes configurable parameters; receiving the user query to change the parameter via a user interaction in which a first visual object in the plurality of visual objects is adjusted, wherein the first visual object includes the parameter.

In some aspects, the techniques described herein relate to a method, wherein generating, for display on the computing device, the user interface including the plurality of visual objects includes adjusting an appearance of the plurality of visual objects based on a complexity level of the user.

In some aspects, the techniques described herein relate to a method, further including: generating, for display on a computing device, an execution result of the modified version of the pre-existing scientific model.

In some aspects, the techniques described herein relate to a method, wherein the pre-existing scientific model is a computational mathematical model used for modeling one or more of: ordinary differential equations, partial differential equations, stochastic modelling, discrete models, Monte Carlo methods, dense functional theory, and Discrete Fourier transform (DFT) approaches.

In some aspects, the techniques described herein relate to a method, wherein the pre-existing scientific model includes a machine learning model.

In some aspects, the techniques described herein relate to a method, wherein the parameter is one or more of: (1) an attribute of a training dataset for the machine learning model, (2) a variable in a training algorithm of the machine learning model, (3) a layer of the machine learning model, and (4) a learned weight or bias of the machine learning model.

In some aspects, the techniques described herein relate to a method, wherein the first machine learning model and the second machine learning model are large language models.

In some aspects, the techniques described herein relate to a method, wherein the user query includes a text that describes the pre-existing scientific model.

In some aspects, the techniques described herein relate to a method, wherein the text is one of: a research publication, a textbook, an academic journal, a lecture slide deck, an article, or notes.

In some aspects, the techniques described herein relate to a method, wherein the pre-existing scientific model is wrapped into an object oriented model including object instances that are connected via a virtual connection mechanism, wherein the object instances are displayed on a user interface as visual objects.

In some aspects, the techniques described herein relate to a method, wherein the visual objects are used as wrappers, wherein at least one visual object allows execution in the object oriented model.

In some aspects, the techniques described herein relate to a method, wherein the parameter of the pre-existing scientific model is mapped to a wrapper parameter that can be created, deleted, modified, or retrieved via chained object model messages.

In some aspects, the techniques described herein relate to a method, where the pre-existing scientific model is wrapped around a chained model.

It should be noted that the methods described above may be implemented in a system comprising a hardware processor. Alternatively, the methods may be implemented using computer executable instructions of a non-transitory computer readable medium.

In some aspects, the techniques described herein relate to a system for executing a model editor, including: at least one memory; and at least one hardware processor coupled with the at least one memory and configured, individually or in combination, to: receive a user query to change a parameter in a pre-existing scientific model; execute a first machine learning model configured to detect the parameter in a code of the pre-existing scientific model, wherein the first machine learning model outputs at least one fragment of the code that is associated with the parameter; execute a second machine learning model configured to: receive both the user query and the at least one fragment of the code as inputs; and generate a new part of the code for the at least one fragment, wherein the new part of the code changes the parameter in accordance with the user query; modifying the code of the pre-existing scientific model to include the new part of the code; and output a modified version of the pre-existing scientific model with the modified code.

In some aspects, the techniques described herein relate to a non-transitory computer readable medium storing thereon computer executable instructions for executing a model editor, including instructions for: receiving a user query to change a parameter in a pre-existing scientific model; executing a first machine learning model configured to detect the parameter in a code of the pre-existing scientific model, wherein the first machine learning model outputs at least one fragment of the code that is associated with the parameter; executing a second machine learning model configured to: receive both the user query and the at least one fragment of the code as inputs; and generate a new part of the code for the at least one fragment, wherein the new part of the code changes the parameter in accordance with the user query; modifying the code of the pre-existing scientific model to include the new part of the code; and outputting a modified version of the pre-existing scientific model with the modified code.

The above simplified summary of example aspects serves to provide a basic understanding of the present disclosure. This summary is not an extensive overview of all contemplated aspects, and is intended to neither identify key or critical elements of all aspects nor delineate the scope of any or all aspects of the present disclosure. Its sole purpose is to present one or more aspects in a simplified form as a prelude to the more detailed description of the disclosure that follows. To the accomplishment of the foregoing, the one or more aspects of the present disclosure include the features described and exemplarily pointed out in the claims.

### BRIEF DESCRIPTION OF THE DRAWINGS

The accompanying drawings, which are incorporated into and constitute a part of this specification, illustrate one or more example aspects of the present disclosure and, together with the detailed description, serve to explain their principles and implementations.

FIG. 1 is a block diagram illustrating a system for executing parameter changes in scientific models using machine learning.

FIG. 2 is a block diagram illustrating a system for executing a scientific model visualizer and editor.

FIG. 3 depicts an example user interface of the model visualizer and editor.

FIG. 4 illustrates a flow diagram of a method for executing parameter changes in scientific models using machine learning.

FIG. 5 presents an example of a general-purpose computer system on which aspects of the present disclosure can be implemented.

he accompanying drawings, which are incorporated into and constitute a part of this specification, illustrate one or more example aspects of the present disclosure and, together with the detailed description, serve to explain their principles and implementations. IG. 1 is a block diagram illustrating a system for executing parameter changes in scientific models using machine learning. IG. 2 is a block diagram illustrating a system for executing a scientific model visualizer and editor. IG. 3 depicts an example user interface of the model visualizer and editor. IG. 4 illustrates a flow diagram of a method for executing parameter changes in scientific models using machine learning. IG. 5 presents an example of a general-purpose computer system on which aspects of the present disclosure can be implemented.

### DETAILED DESCRIPTION

Exemplary aspects are described herein in the context of a system, method, and computer program product for generating and executing a machine learning (ML)-based scientific model editor. Those of ordinary skill in the art will realize that the following description is illustrative only and is not intended to be in any way limiting. Other aspects will readily suggest themselves to those skilled in the art having the benefit of this disclosure. Reference will now be made in detail to implementations of the example aspects as illustrated in the accompanying drawings. The same reference indicators will be used to the extent possible throughout the drawings and the following description to refer to the same or like items.

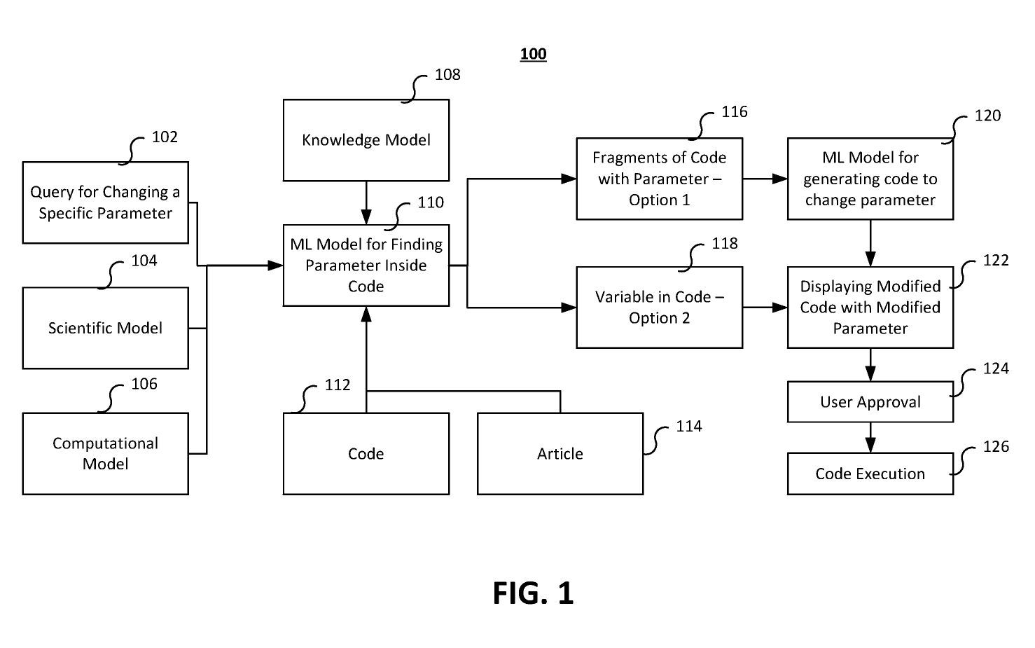

FIG. 1 is a block diagram illustrating system 100 for executing parameter changes in scientific models using machine learning. System 100 features a scientific model 104 and/or computational model 106, both of which are software made up of code.

Computational model 106 is a type of scientific model that uses algorithms and computer simulations to study complex systems. Scientific model 104 may be used to characterize behavior in the physical world. For example, scientific model 104 may be part of an autonomous vehicle’s decision making algorithm and may attempt to capture the affect of various parameters such as aerodynamics, friction, weather, etc., on the vehicle’s movement. In another example, scientific model 104 may be employed to understand and predict biological processes. For instance, scientific model 104 may be integrated into a healthcare diagnostic system to simulate the progression of diseases like cancer. This model may incorporate various parameters such as genetic factors, environmental influences, and treatment responses to predict how a tumor might grow or shrink over time, thereby aiding in personalized treatment planning and decision-making.

In some aspects, the pre-existing scientific model is a computational mathematical model used for modeling one or more of: ordinary differential equations, partial differential equations, stochastic modelling, discrete models, Monte Carlo methods, dense functional theory, and Discrete Fourier transform (DFT) approaches.

In some aspects, scientific model 104 is wrapped into an object oriented model comprising object instances that are connected via a virtual connection mechanism. The object instances may be displayed on a user interface as visual objects. In some aspects, the visual objects are used as wrappers such that at least one visual object allows execution in the object oriented model. In some aspects, scientific model 104 is wrapped around a chained model.

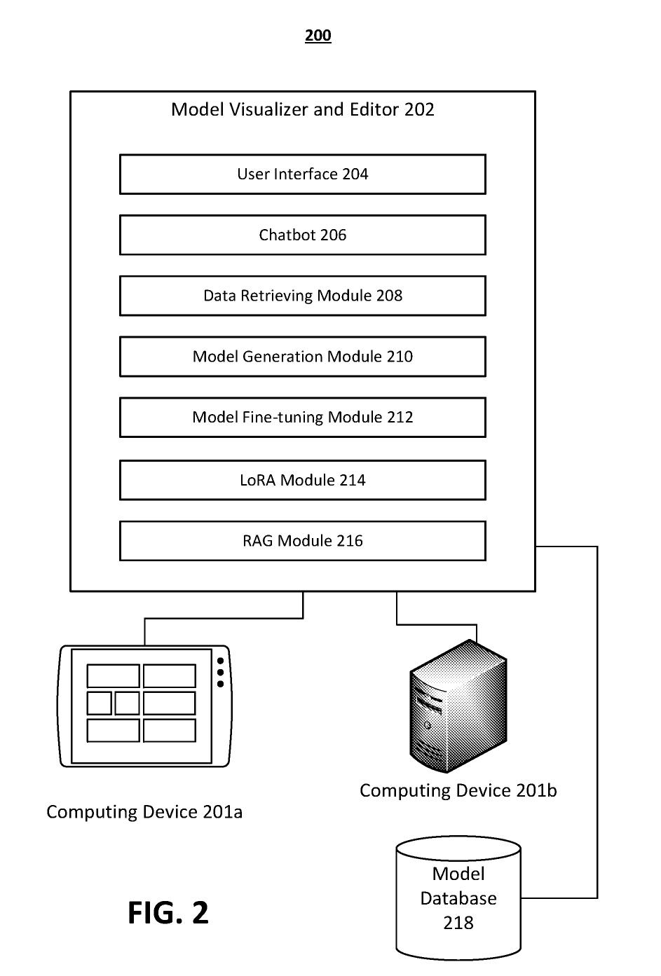

A user may be interested in adjusting parameters of a scientific model 104 and/or computational model 106. In an exemplary aspect, a user may provide a query 102 for changing a specific parameter. For example, the user may adjust a friction coefficient of scientific model 104 that is used for autonomous driving. There are many approaches to changing the parameter. For example, the user can remove the parameter altogether, replace the parameter with a different parameter (e.g., change friction coefficient to wind coefficient to see whether the movement of the vehicle is better captured), adjust a value of the parameter (e.g., change the coefficient from 1.5 to 3.7), add a new parameter that receives the parameter as an input, etc. The user may specify the specific changes requested in the query (received by a user interface such as UI 204 described in FIG. 2).

In some aspects, the parameter of scientific model 104 is mapped to a wrapper parameter that can be created, deleted, modified, or retrieved via chained object model messages.

ML model 110 is configured to find the parameter inside code 112 of scientific model 104 and/or computational model 106 based on the query. In some aspects, an additional input of ML model 110 is an article 114 that describes scientific model 104 and/or computational model 106. Article 114 may be any type of document that describes a scientific or computational model (e.g., a research paper). In some aspects, an additional input of ML model 110 is content from knowledge model 108, which includes information about scientific model 104 and/or computational model 106.

Training ML model 110 to identify parameters within the code of scientific model 104 and/or computational model 106 may first involve data collection, where a comprehensive dataset is curated. This dataset includes labeled examples of code snippets from scientific and computational models, with annotations indicating the parameters and their roles. The dataset may be further enriched with textual data from articles that describe these models, providing contextual and domain-specific knowledge. Additionally, structured data from a knowledge model (e.g., knowledge model 108) is integrated, offering a semantic understanding of the models, including definitions, parameter relationships, and historical context.

In some aspects, the training process may employ supervised learning techniques, where ML model 110 is exposed to this labeled dataset. The model architecture may be a neural network (e.g., a large language model) designed to handle both code and text inputs. For instance, a transformer-based model like BERT or GPT may be adapted to process and understand the syntax and semantics of code, as well as the natural language descriptions from articles and knowledge models.

During training, ML model 110 undergoes forward and backward propagation. In forward propagation, ML model 110 may make predictions about parameter identification based on the input data. The loss function (e.g., cross-entropy loss for classification tasks) may quantify the difference between the predicted and actual parameter labels. Backward propagation may involve adjusting the model's weights using optimization algorithms like Adam or stochastic gradient descent to minimize this loss.

ML model 110 may be iteratively trained over multiple epochs, with each epoch refining its ability to discern patterns and relationships in the data. Techniques such as dropout and batch normalization are employed to prevent overfitting and ensure generalization. The model's performance is evaluated using a validation set, and hyperparameters are tuned to optimize accuracy and efficiency.

Once trained, ML model 110 may effectively parse complex code structures, leveraging the contextual insights from articles and the structured knowledge from the knowledge model to accurately identify and understand parameters within scientific and computational models. This capability enhances the model's application in automating code analysis, optimizing model development, and facilitating decision-making processes in various scientific and engineering domains.

ML model 110 may output fragments of code 116 with the parameter or variable 118. Fragments of code 116 indicate that that parameter has been detected as is. Variable 118 indicates that multiple variables in the code may be combined to form the requested parameter. For example, if a friction coefficient is found in code 112, fragments of code 116 may be different portions of code 112 where a friction coefficient is detected. In a different example, if a friction coefficient is not found, but a combination of found variables such as tire type, weather condition, temperature, and ground type are detected, said variables and their associated code is provided in variables 118.

The outputs of ML model 110 may be input into ML model 120, which is configured to generate code that modifies the parameter as requested by the user. Consider a scenario in which query 102 indicates that the friction coefficient should be given twice the weight for making driving decisions by the autonomous vehicle. The fragment of code that features friction coefficient may be input into ML model 120 along with this query 102. ML model 120 may output modified code in which the weight of the friction coefficient is doubled. In some aspects, the modified code may be displayed on UI 204 as described by block 122. The user may review the modified code and provide user approval 124 via UI 204. Subsequent to user approval, code execution 126 occurs with the modified version of code 112 output by ML model 120.

In some aspects, training ML model 120 to modify code based on user requests involves a comprehensive and technically detailed process. Initially, the training begins with data collection, where a diverse dataset of code snippets and corresponding user queries is gathered. These queries specify the desired modifications, such as altering parameter weights or changing logic within the code. The collected data may undergo preprocessing to ensure consistency and quality, which includes tokenizing the code snippets, normalizing syntax, and encoding user queries into a machine-readable format.

The model architecture for ML model 120 may be a transformer architecture, which is well-suited for understanding and generating code due to its ability to capture context and dependencies within sequences. ML model 120 takes two primary inputs: the code fragment and the user query. These inputs are encoded into embeddings that capture their semantic meaning, with the code represented as a sequence of tokens and the query encoded as a vector highlighting the desired modification. During the training process, a supervised learning approach may be employed, where ML model 120 learns to map input pairs (code, query) to the desired output (modified code). The training dataset may include examples where the correct modifications are already known, allowing ML model 120 to learn from these examples.

A loss function, such as cross-entropy loss, may be used to measure the difference between the model's output and the ground truth, and the model's parameters are updated using backpropagation to minimize this loss. To prevent overfitting, regularization techniques like dropout and weight decay may be employed, and optimization algorithms such as Adam or RMSprop may be used to efficiently update the model's weights during training. The model's performance is evaluated on a validation set, separate from the training data, to assess its ability to generalize to unseen data.

The training process may involve iterative refinement, with multiple training iterations and adjustments made to the architecture, hyperparameters, and training data based on validation results and user feedback. Once trained, ML model 120 is integrated with a user interface (UI 204) that allows users to input queries and review modified code. This interface also facilitates user approval, ensuring that the modifications meet user expectations.

FIG. 2 is a block diagram illustrating system 200 for generating a scientific model visualizer and editor 202. Scientific model visualizer and editor 202 may include all components and functionality described in FIG. 1.

Consider an example in which a user is reviewing a research publication that describes the training and execution of a scientific model such as a machine learning (ML) classifier created for a particular purpose (e.g., classifying whether an input image depicts a specific item). The model visualizer and editor 202 is configured to extract information about the scientific model from the research publication and generate a configurable version for the user to interact with. For example, the model visualizer and editor 202 may visualize a training dataset, a training algorithm, a testing dataset, and an inference algorithm for the user. The initial configuration of the scientific model may be exactly as described in the research publication. For example, if the training dataset takes images from a particular source (e.g., a website) as indicated in the publication, the model visualizer and editor 202 will extract the same dataset from said source. The user can then interact with the visualization by tweaking configurations based on his/her preferences. For example, if the training algorithm does not use boosting to bolster the training samples in the training dataset, the user may include a boosting algorithm (e.g., Adaboost) in the training algorithm.

In an exemplary aspect, model visualizer and editor 202 includes user interface (UI) 204, chatbot 206, data retrieving module 208, model generation module 210, model fine-tuning module 212, low rank adaption (LoRA) module 214, and retrieval augmented generation (RAG) module 216. In some aspects, model visualizer and editor 202 may be executed by computing device 201a and/or computing device 201b. For example, computing device 201a may be a laptop, a desktop computer, a tablet, a smartphone, etc., that includes a display capable of outputting user interface 204. In some aspects, computing device 201b is a server (e.g., situated locally or in the cloud) that executes certain modules of model visualizer and editor 202 and transmits the results to computing device 201a for display. In this scenario, the processing involved in generating/regenerating the scientific model is deferred to the computing device 201b for efficiency.

UI 204 of model visualizer and editor 202 enables users to manipulate parameters of machine learning models and view them in an intuitive manner. Accordingly, the user interface offers many benefits such as ease of exploration, hypothesis testing, accessibility, visualization, collaboration, and outreach.

In terms of ease of exploration, UI 204 allows users to explore the effects of different parameters quickly and intuitively. They can adjust parameters in real-time and observe how these changes impact the model's behavior. This iterative process facilitates a deeper understanding of the model's dynamics and helps researchers identify optimal parameter configurations.

In terms of hypothesis testing, users often develop hypotheses about how certain parameters might affect the outcomes of their models. UI 204 enables them to test these hypotheses efficiently by adjusting parameters and observing the resulting changes. This iterative experimentation is crucial for validating hypotheses and refining scientific theories.

In terms of accessibility, not all researchers may have expertise in programming or the specific modeling framework used in a research paper. UI 204 provides a more accessible interface for interacting with the model, allowing a broader range of researchers to engage with the research and contribute to its advancement.

In terms of visualization, many models are complicated with several inputs and outputs at different layers. UI 204 presents the models as a chain of objects so that the user can determine what each object of the model is used for specifically.

In terms of collaboration, collaborative research often involves multiple researchers with different backgrounds and expertise. UI 204 facilitates collaboration by providing a common platform where researchers can interact with models, share insights, and collectively explore different parameter configurations. This collaborative approach can lead to more robust analyses and discoveries.

Lastly, in terms of education and outreach, beyond the research community, UI 204 can also serve as an educational tool for students, educators, policymakers, and the general public. By providing an intuitive interface for interacting with complex models, UI 204 can help convey scientific concepts more effectively and foster greater public understanding of scientific research.

In an exemplary aspect, a user may access UI 204 and request to generate a pre-existing scientific model. This model may be one of a plurality of scientific models stored in a model database 218 of model visualizer and editor 202. In some aspects, the model is described in a text provided by the user. For example, the user may upload a text document via UI 204. Data retrieving module 208 is configured to retrieve information about the model described in the uploaded document. This document may be a research paper, an academic journal, a textbook, a lecture slide deck, notes, an article, or any other form of written content that includes information about a specific model (e.g., a machine learning model, a statistical model, a mathematical model, or any other kind of model that the system is designed to work with).

Data retrieving module 208 scans the document, identifies sections or passages that include details about the model, and extracts this information for further processing. Data retrieving module 208 is configured to recognize specific types of information relevant to the model. This may include details such as the architecture of the model, its parameters, its training data, its performance metrics, and any other relevant information that would be useful for generating outputs or performing further analysis.

More specifically, data retrieving module 208 may first parse the text document provided by the user. Parsing involves breaking down the text into smaller, more manageable units such as sentences, paragraphs, or sections. This step prepares the document for further analysis. Module 208 may be configured to recognize specific keywords or phrases that indicate relevant information about the model. These keywords could include terms such as "model architecture," "training data," "parameters," "performance metrics," etc. By identifying these keywords, the module can pinpoint sections of the document that are likely to contain information about the model. In some aspects, module 208 considers the surrounding text to disambiguate the meaning of words or phrases and to ensure that the extracted information is relevant to the model being described. For example, it may look for cues such as headings, section titles, or introductory phrases that indicate the beginning of a description of the model.

Once the relevant sections of the document are identified, module 208 may utilize natural language processing (NLP) techniques to extract structured data from the unstructured text. NLP algorithms can analyze the syntactic and semantic structure of the text to understand the relationships between words and phrases. For example, module 208 may utilize named entity recognition (NER) to identify specific entities such as model names, data sources, or evaluation metrics mentioned in the text.

In addition to keyword recognition, module 208 may employ pattern matching techniques or regular expressions to identify specific patterns or formats that are commonly used to describe models. For instance, certain types of models may be described using a standard template or format (e.g., outlined in a table), and module 208 can use pattern matching to extract information based on these templates.

In some aspects, module 208 calls RAG module 216 to aid in data retrieval. RAG module 216 combines elements of both retrieval-based and generation-based approaches to natural language understanding and generation. The retrieval component of RAG module 216 may be utilized to retrieve relevant information from the text document provided by the user. This module 216 typically involves indexing the document corpus and retrieving passages or documents that are most relevant to a given query or context. In this case, the query may be related to the model being described, and the retrieval component would retrieve passages from the document that includes information about the model.

Once the relevant passages are retrieved, the RAG module 216’s generation component can be used to understand and extract structured information from these passages. This involves processing the retrieved text to identify key facts, entities, and relationships related to the model. RAG module 216 may employ techniques such as named entity recognition, syntactic parsing, and semantic analysis to understand the content of the retrieved passages.

Suppose that from a block of text, module 208 and/or module 216 extracts information detailing the source of a training dataset (e.g., the URL of a website), the size of the training dataset (e.g., 500 images), the type of model executed (e.g., a Bayes classifier), the training algorithm (e.g., indicative of the target accuracy, the use of gradient descent, etc.), and the parameters of the model (e.g., learning rate, number of layers, dropout rate, batch size, etc.). Using this, model generation module 210, which may be a large language model, may write the code for recreating the model described in the text. Model generation module 210 may be trained using an input vector with sample extracted information and the corresponding code used to employe the extracted information in a machine learning model.

In some aspects, a model may be made up of a plurality of components. For example, if the pre-existing scientific model is a machine learning model, the components may include, but are not limited to, a training dataset, a training algorithm, and default training parameters. Model visualizer and editor 202 204 may generate, for display on computing device 201a, UI 204 comprising a plurality of visual objects corresponding to the plurality of components. These plurality of visual objects (interchangeable with active object) are visually connected in a chain representing a workflow, and each visual object includes configurable parameters.

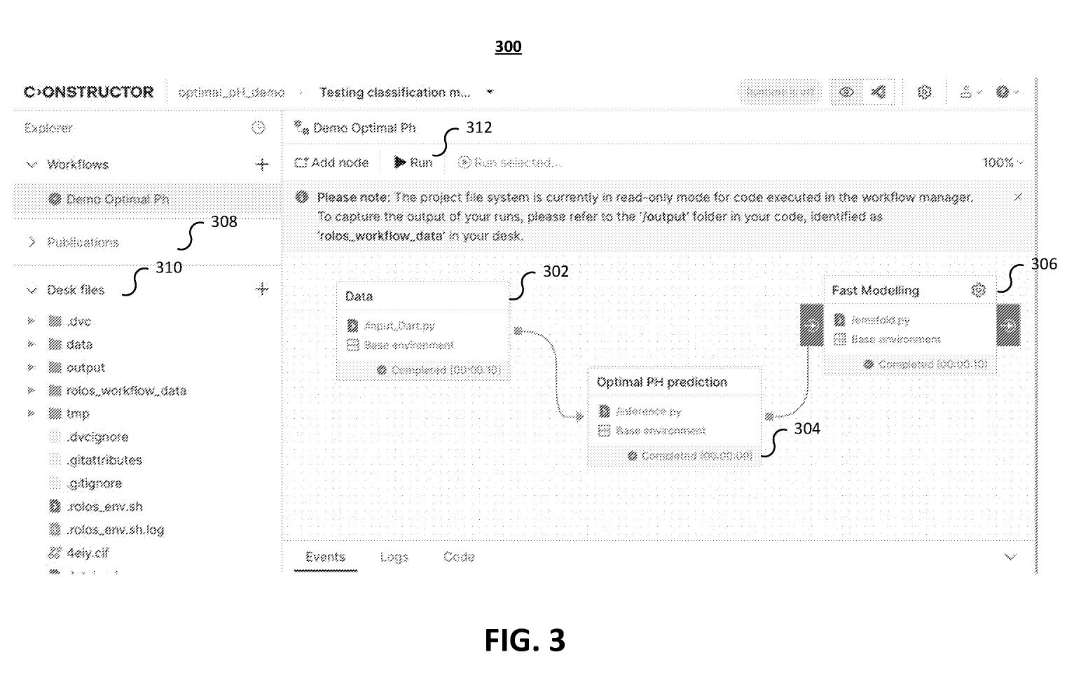

FIG. 3 depicts an example UI 204 that includes visual objects 302-306, Each visual object is a “gray box” that indicates the type of data being generated. For example, visual object 302 is labelled “data,” visual object 304 is labelled “optimal PH prediction,” and visual object 306 is labelled “fast modelling.” The visual objects include a reference (e.g., to a location in storage where there are additional details about the training dataset comprised in “data”) such as “/input_Dart.py” in visual object 302. Furthermore, each visual object is labeled with a completion time (e.g., 10 seconds). UI 204 connects visual object 302 to visual object 304, and visual object 304 to visual object 306. These connections provide an order in which the visual objects are to be executed. For example, when the user hits the run button 312, the component associated with visual object 302 is executed before the component associated with visual object 304. The files retrieved by module 208 are listed in sidebar 310. The publications from which the data was extracted is listed in sidebar 308.

In some aspects, model visualizer and editor 202 configures UI 204 based on the expertise of the user. For example, model visualizer and editor 202 may adjust an appearance of the plurality of visual objects based on a complexity level of the user. The complexity level is a score that combines user preference and user expertise and is used to determine how much information to show on the UI 204. For instance, novice users or those who prefer simplicity may be presented with streamlined visualizations and limited control options to avoid overwhelming them, while advanced users might have access to more intricate representations and a wider range of editing tools. When calculating the complexity level of the user, model visualizer and editor 202 may consider various factors such as user academic level, user profession, usage history of model visualizer and editor 202, interactions with UI 204, or explicit user input (e.g., manual selection of preference). Model visualizer and editor 202 may receive this information directly from the user when creating a user profile via UI 204. For example, if the user is a data scientist, the complexity level (e.g., a score out of 10), may be 9/10. If the user is a freshman college student, the complexity level may be 6/10. For higher complexity levels, model visualizer and editor 202 may present a wider range of configurations to modify. For example, model visualizer and editor 202 may use jargon that a data scientist will be comfortable with and may enable the user to change parameters such as batch size of a machine learning model. In contrast, for lower complexity levels, model visualizer and editor 202 may present fewer configurable parameters on UI 204 and may simplify the appearance of the gray boxes. In some aspects, each complexity level (e.g., 1, 2, 3, 4, etc.) has a specific set of configurable parameters that are shown on UI 204. For example, visual objects shown in FIG. 3 may be set for a low complexity level (e.g., 2/10).

After model generation module 210 generates the pre-existing scientific model on UI 204 for the user to interact with, model visualizer and editor 202 may receive, via UI 204, a user request to modify a first configurable parameter of a first visual object in the plurality of visual objects. In some aspects, the user provides requests via chatbot 206, which is a large language model configured to receive user requests and execute them on model visualizer and editor 202. For example, the user may type in a command stating “reduce the training dataset of this model from 300 samples to 150 samples.” Chatbot 206 parses this command to change the size of the dataset in visual object 302. In this case, the first configurable parameter is training dataset size. In general, the first configurable parameter can be one of: (1) an attribute of the training dataset, (2) code in the training algorithm, (3) a learned weight. An attribute of the training dataset may include, but is not limited to, a size of the dataset, the structure of the dataset, the values within each training vector, and the type of training vector. Code in the training algorithm may include, but is not limited to, the number of iterations that the algorithm goes through, the threshold accuracy rate, a learning rate, the techniques used within the training algorithm (e.g., gradient descent, boosting, etc.). If the model is a neural network, the components may be individual layers. Accordingly, the training algorithm modification may include a change in the number of neurons, the number of layers, the function of each layer, etc. Lastly, pretrained models have certain learned weights. The user may adjust a learned weight to see how it affects the output of the model.

In response to receiving a request to modify a first configuration parameter, module 210 modifies a first component of the pre-existing scientific model that corresponds to the first configurable parameter. For example, if the parameter is the dataset size, the corresponding component is the dataset itself. Suppose that the user wishes to reduce the amount of samples used for training. For example, the user may select visual object 302, which opens a menu enabling the user to adjust the configuration parameter. In response to receiving the user request to modify, model visualizer and editor 202 may remove the amount of samples from the training dataset. Alternatively, the user interacts with chatbot 206 to make the modification.

Module fine-tuning module 212 may then retrain the model in accordance with the modification (e.g., by training the classifier using the updated training dataset). Model visualizer and editor 202 updates the visual object (e.g., to show the modification) and generates, for display on computing device 201a, a performance result of the pre-existing scientific model with the first component modified. For example, UI 204 may display visual object 302 as indicating that the training dataset size has been reduced. The performance result may be an accuracy of the model. For example, the original accuracy of the model prior to modification may be 95%. After the modification, UI 204 may display the accuracy of the modified model to be 90%. Accordingly, the user may continue to alter other configurable parameters (e.g., a second configurable parameter, a third configurable parameter, etc.) or merge the model with another model and view the performance results for each modification.

In some aspects, modifying the first component comprises fine-tuning the machine learning model based on the first configurable parameter using low-ranked adaption (LoRA).

In some aspects, model visualizer and editor 202 is a platform for scientists and researchers (non-ML and ML) and utilizes tools such as “smart article,” Liquid Knowledge Platform (LKP), and Active Knowledge Objects handling. Model visualizer and editor 202 generalizes a nested graph (interchangeably used with chain) of workflow of models, including ML, with more clarity and understanding of model components and their interconnections. In some aspects, model visualizer and editor 202 employs strict partial order (e.g., algebra/set) and self-similar groups. Model visualizer and editor 202 may further implement a controllable “gray box” approach for the structured disclosure of composed objects.

In some aspects, model visualizer and editor 202 has integration with ML and examines the presentation of machine learning models in publications to grasp their architecture, data, and associated diagrams. Model visualizer and editor 202 further generates a user-friendly interface that may include a chat-like interaction with the user. The user interface may visually represent problems, data sets, computations, workflows, versions, etc., enabling the user to play with parameters, data, computation, ML models, security, etc., and distribute results. Model visualizer and editor 202 may further reproduce computations and may be with updated parameters.

A model is represented on UI 204 with the following components according the model visualizer and editor 202:
1. Active object (instance object): The main element of the model represented as a gray box with input and output arrows, typically run as a function or program somewhere.
2. Message processing: Objects evaluate message types and parameters, choosing either to process these messages internally or relay them to a default output channel.
3. Composition of objects: Combining multiple objects creates a compositional object with its own input and output, behaving similarly to a chain of objects.
4. Sequential Hierarchy: Objects are systematically ordered based on their placement in the chain of message processing, indicating a clear precedence relationship.
5. API: Enables efficient message handling and action ordering in code with immediate or buffered execution, easily extendable to distributed systems using interconnected stubs for transparent extension.

An active knowledge object (AKO) is a retractable/redistributable single file that may be downloaded or may be pointed to a Content Repository Platform (CRP) instance with built-in instantiation instruction. In some aspects, the AKO may be a container or virtual machine snapshot.

After installation, the AKO file can be run. In some aspects, the file may be stored inside a local (PC) container made for lightweight objects (via local CRP). In some aspects, the AKO file may be integrated with a local or remote large language model (LLM) or ML model (e.g., with local LM Studio or OpenAI API). In some aspects, the AKO file may run via remote CRP and may redirect messages from local to remote instances.

In some aspects, model visualizer and editor 202 includes a chatbot 206. After installation, the chatbot 206 provides a text/voice/avatar interface using an LLM. For example, the user may ask questions about an article, object content, models, data, and/or references via the UI 204. Chatbot 206 may then generate an answer and respond to user requests.

Model visualizer and editor 202 may include built-in code that can be run locally or inside CRP (e.g., Python). Model visualizer and editor 202 assumes the repetition of computations made by article authors, pointed to their dataset (if possible). Model visualizer and editor 202 enables the editing of parameters, code and workflow (e.g., allow modification of simple model parameters and allow update of workflow, objects connections, code, etc. (probably via CRP online editor only)). A user can type in or speak commands/requests to chatbot 206 for active editing of parameters, migrating of calculations, and generating of plots/diagrams. For example, the user may enter the command “retrain with 80% of the dataset, use rest dataset for benchmarking and run in Azure cloud.”

Model visualizer and editor 202 may have active and passive components. For active components, model visualizer and editor 202 may have executables that run an environment, compiled for the platform (API). Model visualizer and editor 202 may further have containers, virtual machines, etc., that can be distributed/balanced with transparent messaging and migration. Model visualizer and editor 202 may further have a database server, which may be separate or near executable(s), SQL, VectorDB, or integrated (as a library). In terms of passive components, model visualizer and editor 202 may have internal storage with configuration files, data sets, and program code (e.g. python). These components may be distributed and may have versioning/snapshotting. A passive component may also be external storage with information stored outside of a platform (e.g., S3 blob storage) with access via link and/or requiring authorization/configurations (like URL/URI).

In terms of lifecycle, model visualizer and editor 202 may have a multi-workflow that assumes different stages (e.g., dataset preparation, model training, and inference). Model visualizer and editor 202 may have transparent data sharing by which workflows can seamlessly exchange data. Model visualizer and editor 202 may have workflows management that allow creation or updating using CRP's nested objects editor or a chatbot. Model visualizer and editor 202 may utilize a library of objects, messages, and code wrappers. Model visualizer and editor 202 is suitable for use by various roles from core developers to end-users. Model visualizer and editor 202 also have pre-built resources that involve accessing a CRP's library for ready-to-use objects and model packages.

Model visualizer and editor 202 replicates existing workflows or models and provides database options -supporting SQL, VectorDB, or integrated libraries. Model visualizer and editor 202 may manage local/cloud resources including CPU, GPU, and network specs. Model visualizer and editor 202 may handle external resource authorization and price estimation. Model visualizer and editor 202 may start local/cloud instance in a configured environment. Model visualizer and editor 202 may process and prepare results for presentation. Model visualizer and editor 202 may wrap-up results to redistributable AKO for colleagues/publication. Model visualizer and editor 202 may create artefacts such as slideshow/avatar presentations, text, static articles, grant proposals, thesis, reports, etc.

In an object model composition method, model visualizer and editor 202 offers simple programming language API and straightforward visual representation. The visual editor enables manipulation of objects and chains without revealing their internal structure. Model visualizer and editor 202 is also adaptable to graph-based scenarios. Model visualizer and editor 202 executes a layered queue system to ensure complete processing of all messages and their subsequent derivatives. Model visualizer and editor 202 further supports both synchronous and asynchronous message processing. For example, model visualizer and editor 202 may use depth-first traversal messages, which are fully processed through a chain of handlers until one returns zero - indicating complete consumption of the message and its derivatives. Model visualizer and editor 202 may use breadth-first traversal messages, where messages are queued for processing, enabling clear tracking of completion. Model visualizer and editor 202 has effective non-parallel and non-pre-emptive methods, which eliminate the need for mutexes, though they remain an option.

The advantages of the model visualizer and editor 202 are as follows: (1) formal representation: This model is structured as algebra, introducing systematic organization to the modelling process. It aligns well with the 'self-similar groups' model widely utilized in computer science. (2) gray box control: model visualizer and editor 202 provides selective visibility into the model's structure and important parameters, allowing focus on crucial aspects while simplifying the rest, and (3) visual understandability in which the model offers a visually intuitive format for complex models, simplifying interaction and information abstraction. This method is partially employed in well-known IDEs, such as Xcode.

Formal algebra, which includes mathematical structures and operations, can be seen in some programming language design and concepts. For example:

Boolean Algebra: Logic gates and Boolean algebra are fundamental to the design of computer circuits and form the basis for conditional statements in programming languages.

Set Theory: Many programming languages and frameworks incorporate principles from set theory, particularly in the way they handle data structures and collections.

Algebraic Data Types (ADTs): Some programming languages, especially in the functional programming paradigm, use algebraic data types to model data structures.

Algebraic Expressions: Programming languages often involve the use of algebraic expressions, which follow mathematical rules for combining variables, constants, and operations.

Category Theory in Functional Programming: Category theory, a branch of abstract algebra, has influenced the design of functional programming languages. Concepts like monads and functors are examples of this influence.

In traditional “math modelling,” computational models like MPI/clustering have been established. With the integration of artificial intelligence (AI), the present disclosure aims to represent and manipulate structured model components of any kind, and be able to blend AI with non-AI elements. This includes handling code, datasets, parameters, and processes like fine-tuning/retraining. The challenge is mapping these elements to the proposed 'chained/pipes' model when seamless integration is needed with the current CRP implementation for jump-start.

In the current research platform, workflows are visualized as interconnected boxes, each indicating significant operations like data-heavy computations. Data sharing is performed via links and designated storage locations. The key components include (1) the main program, which may run Python or external software, accessing relevant data, (2) datasets, with sources local to the code or cloud-based (e.g., Amazon), (3) future additions comprising additional code and data for enhanced platform functionality, and (4) tools, such as Vector DB and chat functionality for context-aware object LLM queries. The platform also has pre-configured resources such as software packages (e.g., Matlab), computational power (e.g., GPUs), storage (e.g., Azure), and a LLM (e.g., local or as API to ChatGPT).

In the decomposition of the ML workflow, model visualizer and editor 202 creates the typical ML model structure with boxes and arrows. Every box represents an internal operation, like matrix or/and scalar multiplication, softmax/etc. Model visualizer and editor 202 assumes deep reference (data stored “in memory”, locally and typically directly available from any box like “pointer dereference”). Knowledge is interpreted as being stored inside an ML model. Such knowledge includes input encoding (embeddings which may be varied for the same dataset), model architecture (e.g., programming code), weights, and anything used as a part of a data structure (e.g., vectors, trees, etc.).

Model visualizer and editor 202 may combine different models with different data representations in the workflow. In order to support distributed objects messaging (addressing/marshalling/sync/etc), model visualizer and editor 202 provides big and small data “cross-object” access. Model visualizer and editor 202 further keeps the control graph outside, but “iteration criteria” inside the model parts.

Because the user interface enables a user to adjust a model, model visualizer and editor 202 essentially takes a trained model and adds some new “knowledge” into it. Model visualizer and editor 202 further seeks solutions that integrate a standard base with supplementary add-ons. Model visualizer and editor 202 assumes some theoretical formal operations like union, intersection, cartesian product/etc. In an ideal scenario, model visualizer and editor 202 aims for linearity. The outcomes do not rely on the sequence of operations. It should be noted that knowledge from one source should be independent of another.

After trained, a model is represented as a single big data structure. One layer to another layer may be connected via a huge data set (which could be in the same time output of one model part and input of the next part). The internal formats are mostly hidden (could have a processing code access). When attempting to change a model, results potentially scatter across model data. Accordingly, there is no easy way to build a “diff” after the model re-training or fine-tuning. The interaction context is kept small so it does not affect other clients' data later forgotten.

In order modify (add or update) knowledge, model visualizer and editor 202 re-trains on new data existent model, which typically leads to global changes of data. Data modification may involve code updates as well. For example, model visualizer and editor 202 may remove certain layers in a neural network depicted on the user interface and retrain on a new input dataset from different class. Model visualizer and editor 202 may further fine-tune parameters.

When combining different instances of models, model visualizer and editor 202 takes the result of the work of one model and injects it into another. Model visualizer and editor 202 typically connects input/output of the models.

In some aspects, to enhance (add) the knowledge of a base model using an additional model called LoRA Model (Low-Rank Adaptation Model) or a Quantized LoRA variant. This allows for model visualizer and editor 202 to keep data outside of main LLM and easier retraining. LoRA is a method for efficiently adapting large pre-trained machine learning models. It uses small, trainable low-rank matrices to modify the model's weights, enabling significant changes with minimal additional parameters. The LoRA Model fine-tunes the parameters of the base model while keeping its structure unchanged. During inference, the LoRA Model operates concurrently with the base model, adding knowledge and context.

For example, model visualizer and editor 202 may periodically create a new dataset from knowledge/articles for fine-tuning. Model visualizer and editor 202 may also use a LLM to summarize them to bullet point list. Model visualizer and editor 202 generates a question from each summarized bullet and asks the LLM to provide answer to the question from the article using it as a context. Model visualizer and editor 202 then use pairs “question-answer” from new articles as fine-tuning dataset. During the inference stage, a user submits a text request to the top of the model chain. The request is processed by the LoRA Model and the base model. The LoRA model provides additive knowledge and context to the base model's response. The quality of response is evaluated and, if necessary, the question is passed down the chain for further clarification or improvement.

Additive models should have minimal nonlinear interactions to ensure independence and usability with different topics. In the hierarchy of knowledge, models addressing prerequisites should precede those that build upon them. Nearly all fine-tuned LoRA models should be trained on top of the base model. For RAG, it is not that clear how to refer to another part of knowledge as VectorDB in case of obvious precedence on top of hierarchy (other models). Subtraction assumes removal of some LoRA sub-models or retrieval-augmented generation (RAG) database (db) records.

Requests and modifications should be balanced in terms of computational resources and complexity, across the connections. Too heavy requests consume excessive resources without providing reasonable answers, while too light requests may be trivial and lack meaningful insights - finding a middle ground is crucial for efficient knowledge enhancement.

In terms of implementation of a RAG model, model visualizer and editor 202 uses a retrieval model with paragraphs indexed (Bert-like vector (embedding) VectorDB). During inference, model visualizer and editor 202 uses the retrieval model to find relevant paragraphs/whole article, and inject the retrieved text into the main LLM model with a prompt like “using the following information <snippets above> find answer to question <q>” where q is the question. Model visualizer and editor 202 may augment VectorDB with predicted questions/answers and search among them. For heavy data model visualizer and editor 202 uses hierarchical summarization, and gives an answer to each paragraph above. Model visualizer and editor 202 may set benchmarks using a 'human baseline' or similar methods to create a labelled dataset. LoRA gives away 5-10% of accuracy in general. Model visualizer and editor 202 develops a hybrid model with RAG for ongoing data additions and weekly fine-tuning via LoRA. Model visualizer and editor 202 may also use “child tuning” as an add-on technique instead of LoRA or Soft Fine Tuning (SFT).

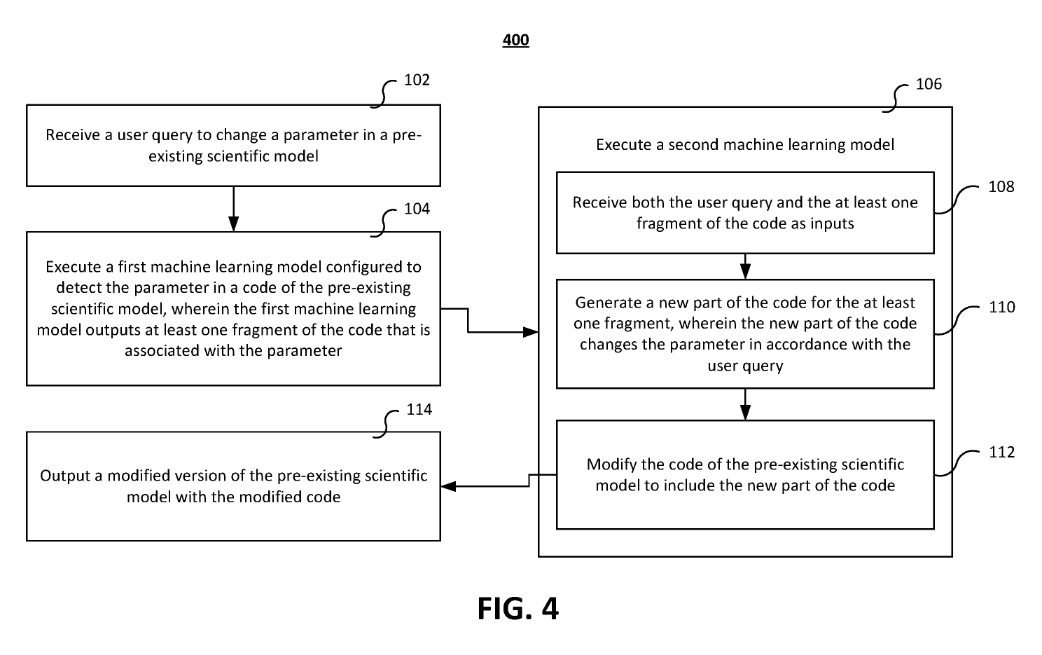

FIG. 4 illustrates a flow diagram of method 400 for executing parameter changes in scientific models using machine learning. At 402, model visualizer and editor 202 receives a user query to change a parameter in a pre-existing scientific model (e.g., scientific model 104).

In some aspects, the user query comprises a text that describes the pre-existing scientific model. For example, the text may be one of: a research publication, a textbook, an academic journal, a lecture slide deck, an article, or notes.

At 404, model visualizer and editor 202 executes a first machine learning model (e.g. ML model 110) configured to detect the parameter in a code (e.g., code 112) of the pre-existing scientific model. The first machine learning model outputs at least one fragment of the code (e.g., fragments of code 116) that is associated with the parameter.

In some aspects, the pre-existing scientific model comprises a machine learning model. Accordingly, the parameter may be one or more of: (1) an attribute of a training dataset for the machine learning model, (2) a variable in a training algorithm of the machine learning model, (3) a layer of the machine learning model, and (4) a learned weight or bias of the machine learning model.

At 406, model visualizer and editor 202 executes a second machine learning model (e.g., ML model 120). In some aspects, the first machine learning model and the second machine learning model are large language models.

Steps 408-412 indicate the actions taken by the second machine learning model. At 408, the second machine leaning model receives both the user query and the at least one fragment of the code as inputs. At 410, the second machine learning model generates a new part of the code for the at least one fragment. The new part of the code changes the parameter in accordance with the user query. At 412, the second machine learning model modifies the code of the pre-existing scientific model to include the new part of the code.

At 414, model visualizer and editor 202 outputs (e.g., on UI 204) a modified version of the pre-existing scientific model with the modified code. In some aspects, model visualizer and editor 202 may further generate, for display on a computing device, an execution result of the modified version of the pre-existing scientific model.

In some aspects, the pre-existing scientific model does not include an explicit value corresponding to the parameter. Accordingly, the code of the pre-existing scientific model detected by the first machine learning model comprises a plurality of sub-parameters that equal the parameter when combined. For example, if the user query involves adjusting a parameter that is a function sub-parameters A, B, and C, but the actual parameter is not found, ML model 110 may attempt to find sub-parameters A, B, and C. In some aspects, ML model 110 may determine the relationship between the parameter and the sub-parameters using one or both of knowledge model 108 and article 114 about scientific model 104.

In some aspects, the user query is received via a user interface (e.g., UI 204). Model visualizer and editor 202 may further identify a plurality of components in the pre-existing scientific model and generate, for display on a computing device, the user interface comprising a plurality of visual objects corresponding to the plurality of components (as shown in FIG. 3). These plurality of visual objects may be visually connected in a chain representing a workflow and at least one visual object includes configurable parameters. In some aspects, the user query to change the parameter is received via a user interaction in which a first visual object in the plurality of visual objects is adjusted. Here, the first visual object includes the parameter.

In some aspects, model visualizer and editor 202 may adjust an appearance of the plurality of visual objects based on a complexity level of the user. For example, if a user is a scientist, the visual objects may be depicted based on scientific terms and high-level relationships. If the user is a programmer, the visual objects may be depicted to show specific functions in the code. The complexity level of the user may be stored in a user profile and may be predefined from a plurality of complexity levels.

In some aspects, scientific model 104 is encapsulated within an object-oriented framework, where it is represented as a series of interconnected object instances. This encapsulation allows the model to be modular and flexible, facilitating easier manipulation and interaction. The object instances are linked through a virtual connection mechanism, which may be a network of nodes where each node represents a specific component or function of the scientific model. This setup enables the model to be displayed on a user interface as visual objects, providing a more intuitive and interactive way for users to engage with the model. For example, in a weather simulation model, different components such as temperature, humidity, and wind speed may be represented as separate visual objects. Users can interact with these objects to adjust parameters or observe their effects on the overall model.

The visual objects serve as wrappers that encapsulate the underlying scientific computations and present them in a user-friendly manner. At least one of these visual objects is designed to allow execution within the object-oriented model, enabling users to run simulations or calculations directly from the interface. This approach not only enhances usability but also allows for real-time interaction and feedback, which is particularly beneficial in complex scientific modeling scenarios.

Additionally, scientific model 104 may be wrapped around a chained model comprising a sequential and/or hierarchical structuring of model components. In a chained model, the output of one component can serve as the input for another, creating a flow of data and computations. For instance, in a biochemical pathway simulation, the output of a reaction may be the input for subsequent reactions, forming a chain of processes. This chaining allows for more sophisticated modeling of systems where interactions and dependencies between components are critical.

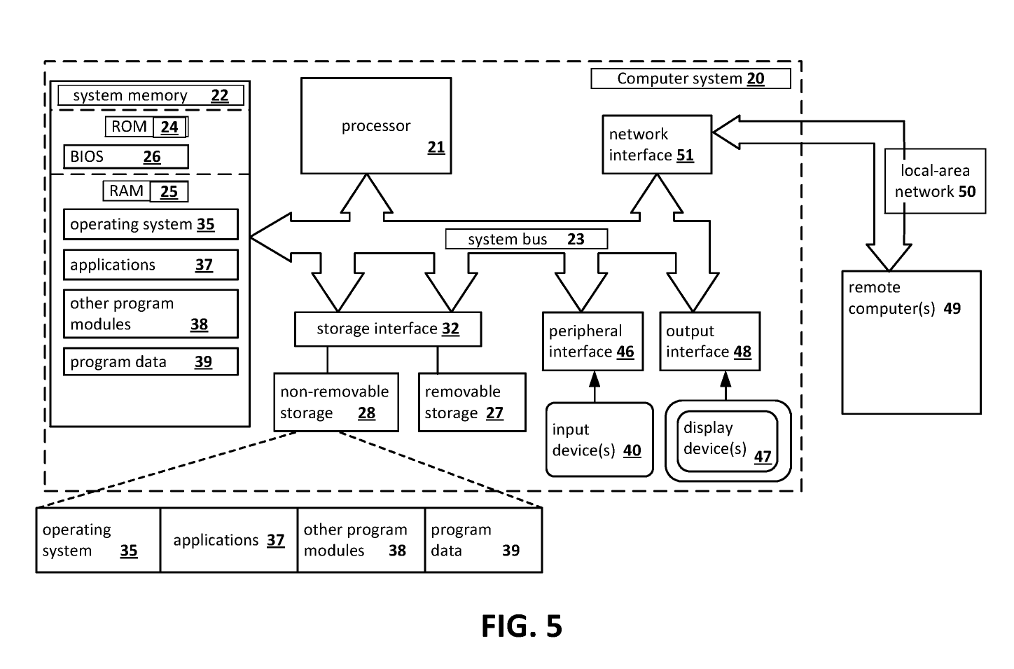

FIG. 5 is a block diagram illustrating a computer system 20 on which aspects of systems and methods for generating a machine learning model editor may be implemented in accordance with an exemplary aspect. The computer system 20 can be in the form of multiple computing devices, or in the form of a single computing device, for example, a desktop computer, a notebook computer, a laptop computer, a mobile computing device, a smart phone, a tablet computer, a server, a mainframe, an embedded device, and other forms of computing devices.

As shown, the computer system 20 includes a central processing unit (CPU) 21, a system memory 22, and a system bus 23 connecting the various system components, including the memory associated with the central processing unit 21. The system bus 23 may comprise a bus memory or bus memory controller, a peripheral bus, and a local bus that is able to interact with any other bus architecture. Examples of the buses may include PCI, ISA, PCI-Express, HyperTransport™, InfiniBand™, Serial ATA, I2C, and other suitable interconnects. The central processing unit 21 (also referred to as a processor) can include a single or multiple sets of processors having single or multiple cores. The processor 21 may execute one or more computer-executable code implementing the techniques of the present disclosure. For example, any of commands/steps discussed in FIGS. 1-4 may be performed by processor 21. The system memory 22 may be any memory for storing data used herein and/or computer programs that are executable by the processor 21. The system memory 22 may include volatile memory such as a random access memory (RAM) 25 and non-volatile memory such as a read only memory (ROM) 24, flash memory, etc., or any combination thereof. The basic input/output system (BIOS) 26 may store the basic procedures for transfer of information between elements of the computer system 20, such as those at the time of loading the operating system with the use of the ROM 24.

The computer system 20 may include one or more storage devices such as one or more removable storage devices 27, one or more non-removable storage devices 28, or a combination thereof. The one or more removable storage devices 27 and non-removable storage devices 28 are connected to the system bus 23 via a storage interface 32. In an aspect, the storage devices and the corresponding computer-readable storage media are power-independent modules for the storage of computer instructions, data structures, program modules, and other data of the computer system 20. The system memory 22, removable storage devices 27, and non-removable storage devices 28 may use a variety of computer-readable storage media. Examples of computer-readable storage media include machine memory such as cache, SRAM, DRAM, zero capacitor RAM, twin transistor RAM, eDRAM, EDO RAM, DDR RAM, EEPROM, NRAM, RRAM, SONOS, PRAM; flash memory or other memory technology such as in solid state drives (SSDs) or flash drives; magnetic cassettes, magnetic tape, and magnetic disk storage such as in hard disk drives or floppy disks; optical storage such as in compact disks (CD-ROM) or digital versatile disks (DVDs); and any other medium which may be used to store the desired data and which can be accessed by the computer system 20.

The system memory 22, removable storage devices 27, and non-removable storage devices 28 of the computer system 20 may be used to store an operating system 35, additional program applications 37, other program modules 38, and program data 39. The computer system 20 may include a peripheral interface 46 for communicating data from input devices 40, such as a keyboard, mouse, stylus, game controller, voice input device, touch input device, or other peripheral devices, such as a printer or scanner via one or more I/O ports, such as a serial port, a parallel port, a universal serial bus (USB), or other peripheral interface. A display device 47 such as one or more monitors, projectors, or integrated display, may also be connected to the system bus 23 across an output interface 48, such as a video adapter. In addition to the display devices 47, the computer system 20 may be equipped with other peripheral output devices (not shown), such as loudspeakers and other audiovisual devices.

The computer system 20 may operate in a network environment, using a network connection to one or more remote computers 49. The remote computer (or computers) 49 may be local computer workstations or servers comprising most or all of the aforementioned elements in describing the nature of a computer system 20. Other devices may also be present in the computer network, such as, but not limited to, routers, network stations, peer devices or other network nodes. The computer system 20 may include one or more network interfaces 51 or network adapters for communicating with the remote computers 49 via one or more networks such as a local-area computer network (LAN) 50, a wide-area computer network (WAN), an intranet, and the Internet. Examples of the network interface 51 may include an Ethernet interface, a Frame Relay interface, SONET interface, and wireless interfaces.

Aspects of the present disclosure may be a system, a method, and/or a computer program product. The computer program product may include a computer readable storage medium (or media) having computer readable program instructions thereon for causing a processor to carry out aspects of the present disclosure.

The computer readable storage medium can be a tangible device that can retain and store program code in the form of instructions or data structures that can be accessed by a processor of a computing device, such as the computing system 20. The computer readable storage medium may be an electronic storage device, a magnetic storage device, an optical storage device, an electromagnetic storage device, a semiconductor storage device, or any suitable combination thereof. By way of example, such computer-readable storage medium can comprise a random access memory (RAM), a read-only memory (ROM), EEPROM, a portable compact disc read-only memory (CD-ROM), a digital versatile disk (DVD), flash memory, a hard disk, a portable computer diskette, a memory stick, a floppy disk, or even a mechanically encoded device such as punch-cards or raised structures in a groove having instructions recorded thereon. As used herein, a computer readable storage medium is not to be construed as being transitory signals per se, such as radio waves or other freely propagating electromagnetic waves, electromagnetic waves propagating through a waveguide or transmission media, or electrical signals transmitted through a wire.

Computer readable program instructions described herein can be downloaded to respective computing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network interface in each computing device receives computer readable program instructions from the network and forwards the computer readable program instructions for storage in a computer readable storage medium within the respective computing device.

Computer readable program instructions for carrying out operations of the present disclosure may be assembly instructions, instruction-set-architecture (ISA) instructions, machine instructions, machine dependent instructions, microcode, firmware instructions, state-setting data, or either source code or object code written in any combination of one or more programming languages, including an object oriented programming language, and conventional procedural programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a LAN or WAN, or the connection may be made to an external computer (for example, through the Internet). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

In various aspects, the systems and methods described in the present disclosure can be addressed in terms of modules. The term "module" as used herein refers to a real-world device, component, or arrangement of components implemented using hardware, such as by an application specific integrated circuit (ASIC) or FPGA, for example, or as a combination of hardware and software, such as by a microprocessor system and a set of instructions to implement the module’s functionality, which (while being executed) transform the microprocessor system into a special-purpose device. A module may also be implemented as a combination of the two, with certain functions facilitated by hardware alone, and other functions facilitated by a combination of hardware and software. In certain implementations, at least a portion, and in some cases, all, of a module may be executed on the processor of a computer system. Accordingly, each module may be realized in a variety of suitable configurations, and should not be limited to any particular implementation exemplified herein.

In the interest of clarity, not all of the routine features of the aspects are disclosed herein. It would be appreciated that in the development of any actual implementation of the present disclosure, numerous implementation-specific decisions must be made in order to achieve the developer’s specific goals, and these specific goals will vary for different implementations and different developers. It is understood that such a development effort might be complex and time-consuming, but would nevertheless be a routine undertaking of engineering for those of ordinary skill in the art, having the benefit of this disclosure.

Furthermore, it is to be understood that the phraseology or terminology used herein is for the purpose of description and not of restriction, such that the terminology or phraseology of the present specification is to be interpreted by the skilled in the art in light of the teachings and guidance presented herein, in combination with the knowledge of those skilled in the relevant art(s). Moreover, it is not intended for any term in the specification or claims to be ascribed an uncommon or special meaning unless explicitly set forth as such.

The various aspects disclosed herein encompass present and future known equivalents to the known modules referred to herein by way of illustration. Moreover, while aspects and applications have been shown and described, it would be apparent to those skilled in the art having the benefit of this disclosure that many more modifications than mentioned above are possible without departing from the inventive concepts disclosed herein.

1. A method for executing a parameter change in a scientific model, the method comprising:
receiving a user query to change a parameter in a pre-existing scientific model;
executing a first machine learning model configured to detect the parameter in a code of the pre-existing scientific model, wherein the first machine learning model outputs at least one fragment of the code that is associated with the parameter;
executing a second machine learning model configured to:
receive both the user query and the at least one fragment of the code as inputs; and
generate a new part of the code for the at least one fragment, wherein the new part of the code changes the parameter in accordance with the user query;
modifying the code of the pre-existing scientific model to include the new part of the code; and
outputting a modified version of the pre-existing scientific model with the modified code.

2. The method of claim 1, wherein the pre-existing scientific model does not include an explicit value corresponding to the parameter, wherein the code of the pre-existing scientific model detected by the first machine learning model comprises a plurality of sub-parameters that equal the parameter when combined.

3. The method of claim 1, wherein the user query is received via a user interface, further comprising:
identifying a plurality of components in the pre-existing scientific model;
generating, for display on a computing device, the user interface comprising a plurality of visual objects corresponding to the plurality of components, wherein the plurality of visual objects are visually connected in a chain representing a workflow, and wherein at least one visual object includes configurable parameters;
receiving the user query to change the parameter via a user interaction in which a first visual object in the plurality of visual objects is adjusted, wherein the first visual object includes the parameter.

4. The method of claim 3, wherein generating, for display on the computing device, the user interface comprising the plurality of visual objects comprises adjusting an appearance of the plurality of visual objects based on a complexity level of the user.

5. The method of claim 1, further comprising:
generating, for display on a computing device, an execution result of the modified version of the pre-existing scientific model.

6. The method of claim 1, wherein the pre-existing scientific model is a computational mathematical model used for modeling one or more of: ordinary differential equations, partial differential equations, stochastic modelling, discrete models, Monte Carlo methods, dense functional theory, and Discrete Fourier transform (DFT) approaches.

7. The method of claim 1, wherein the pre-existing scientific model comprises a machine learning model.

8. The method of claim 7, wherein the parameter is one or more of:
(1) an attribute of a training dataset for the machine learning model,
(2) a variable in a training algorithm of the machine learning model,
(3) a layer of the machine learning model, and
(4) a learned weight or bias of the machine learning model.

9. The method of claim 1, wherein the first machine learning model and the second machine learning model are large language models.

10. The method of claim 1, wherein the user query comprises a text that describes the pre-existing scientific model.

11. The method of claim 10, wherein the text is one of: a research publication, a textbook, an academic journal, a lecture slide deck, an article, or notes.

12. The method of claim 1, wherein the pre-existing scientific model is wrapped into an object oriented model comprising object instances that are connected via a virtual connection mechanism, wherein the object instances are displayed on a user interface as visual objects.

13. The method of claim 12, wherein the visual objects are used as wrappers, wherein at least one visual object allows execution in the object oriented model.

14. The method of claim 12, wherein the parameter of the pre-existing scientific model is mapped to a wrapper parameter that can be created, deleted, modified, or retrieved via chained object model messages.

15. The method of claim 12, where the pre-existing scientific model is wrapped around a chained model.

16. A system for executing a model editor, comprising:
at least one memory; and
at least one hardware processor coupled with the at least one memory and configured, individually or in combination, to:
receive a user query to change a parameter in a pre-existing scientific model;
execute a first machine learning model configured to detect the parameter in a code of the pre-existing scientific model, wherein the first machine learning model outputs at least one fragment of the code that is associated with the parameter;
execute a second machine learning model configured to:
receive both the user query and the at least one fragment of the code as inputs; and
generate a new part of the code for the at least one fragment, wherein the new part of the code changes the parameter in accordance with the user query;
modifying the code of the pre-existing scientific model to include the new part of the code; and
output a modified version of the pre-existing scientific model with the modified code.

17. The system of claim 16, wherein the pre-existing scientific model does not include an explicit value corresponding to the parameter, wherein the code of the pre-existing scientific model detected by the first machine learning model comprises a plurality of sub-parameters that equal the parameter when combined.

18. The system of claim 16, wherein the user query is received via a user interface, and wherein the at least one hardware processor is further configured to:
identify a plurality of components in the pre-existing scientific model;
generate, for display on a computing device, the user interface comprising a plurality of visual objects corresponding to the plurality of components, wherein the plurality of visual objects are visually connected in a chain representing a workflow, and wherein at least one visual object includes configurable parameters;
receive the user query to change the parameter via a user interaction in which a first visual object in the plurality of visual objects is adjusted, wherein the first visual object includes the parameter.

19. The system of claim 18, wherein the at least one hardware processor is further configured to generate, for display on the computing device, the user interface comprising the plurality of visual objects by adjusting an appearance of the plurality of visual objects based on a complexity level of the user.

20. A non-transitory computer readable medium storing thereon computer executable instructions for executing a model editor, including instructions for:
receiving a user query to change a parameter in a pre-existing scientific model;
executing a first machine learning model configured to detect the parameter in a code of the pre-existing scientific model, wherein the first machine learning model outputs at least one fragment of the code that is associated with the parameter;
executing a second machine learning model configured to:
receive both the user query and the at least one fragment of the code as inputs; and
generate a new part of the code for the at least one fragment, wherein the new part of the code changes the parameter in accordance with the user query;
modifying the code of the pre-existing scientific model to include the new part of the code; and
outputting a modified version of the pre-existing scientific model with the modified code.
